(19) United States
(12) Patent Application Publication
(10) Pub. No.: US 2016/0276312 A1
(43) Pub. Date: Sep. 22, 2016

(54) SEMICONDUCTOR DEVICE AND METHOD FOR MANUFACTURING THE SAME

(71) Applicant: KABUSHIKI KAISHA TOSHIBA, Tokyo (JP)

(72) Inventors: Shinya SHIMIZU, Ota Tokyo (JP); Mika KIRITANI, Kawasaki Kanagawa (JP); Ken MURAMATSU, Yokohama Kanagawa (JP)

(21) Appl. No.: 15/061,965

(22) Filed: Mar. 4, 2016

(30) Foreign Application Priority Data
Mar. 19, 2015 (JP) 2015-056981

(51) Int. Cl. H01L 25/065; H01L 25/16; H01L 23/00; H01L 25/00

(52) U.S. Cl. CPC H01L 25/0657; H01L 25/50; H01L 25/16; H01L 24/05; H01L 2225/0651; H01L 2225/06524; H01L 2225/06562; H01L 2225/06575; H01L 2224/04042; H01L 2224/02235; H01L 2924/1434; H01L 2924/1431; H01L 2924/146; H01L 2224/32055; H01L 2224/32054; H01L 2224/32501; H01L 2924/0665

(57) ABSTRACT

A semiconductor device includes a wiring substrate, a first semiconductor chip provided on the wiring substrate, a supporting member provided on the wiring substrate in a region which does not overlap with the first semiconductor chip in a plan view when viewed from a direction perpendicular to the wiring substrate, a resin member provided on the first semiconductor chip, and a second semiconductor chip provided on the supporting member and the resin member. A method for manufacturing a semiconductor device includes providing a first semiconductor chip in a first region on a wiring substrate, providing a supporting member in a second region on the wiring substrate, providing a resin member in at least a portion on the first semiconductor chip, and providing a second semiconductor chip on the supporting member and the resin member.

### CROSS-REFERENCE TO RELATED APPLICATION

This application is based upon and claims the benefit of priority from Japanese Patent Application No. 2015-056981, filed Mar. 19, 2015, the entire contents of which are incorporated herein by reference.

### FIELD

Embodiments described herein relate generally to semiconductor devices and methods for manufacturing the semiconductor device.

### BACKGROUND

A semiconductor device formed by encapsulating a plurality of semiconductor chips in one semiconductor package has been put to practical use.

### DESCRIPTION OF THE DRAWINGS

FIG. 1 is a plan view (I) of a semiconductor device according to a first embodiment.

FIG. 2 is a plan view (II) of the semiconductor device according to the first embodiment.

FIG. 3 is a sectional view taken on the line A-A′ of FIGS. 1 and 2.

FIG. 4 is a sectional view (I) depicting a partially completed semiconductor device using the method for manufacturing the semiconductor device according to the first embodiment.

FIG. 5 is a sectional view (II) depicting a partially completed semiconductor device using the method for manufacturing the semiconductor device according to the first embodiment.

FIG. 6 is a sectional view (III) depicting a partially completed semiconductor device using the method for manufacturing the semiconductor device according to the first embodiment.

FIG. 7 is a plan view of a semiconductor device according to a second embodiment.

FIG. 8 is a plan view of a semiconductor device according to a third embodiment.

### DETAILED DESCRIPTION

Embodiments provide a high-performance and highly reliable semiconductor device and a method for manufacturing such a semiconductor device.

In general, according to one embodiment, a semiconductor device includes a wiring substrate, a first semiconductor chip provided on the wiring substrate, a supporting member provided on the wiring substrate in a region which does not overlap with the first semiconductor chip in a plan view when viewed from a direction perpendicular to the wiring substrate, a resin member provided on the first semiconductor chip, and a second semiconductor chip provided on the supporting member and the resin member.

Hereinafter, a first embodiment will be described with reference to the drawings. Herein, component elements having counterparts or equivalents in different drawings are identified with the same reference characters and the detailed explanations thereof will be appropriately omitted.

Moreover, for the sake of convenience, a direction orthogonal to a wiring substrate 10 will be referred to as a first direction. Unless otherwise specified, an “area” means an area viewed from above.

### First Embodiment

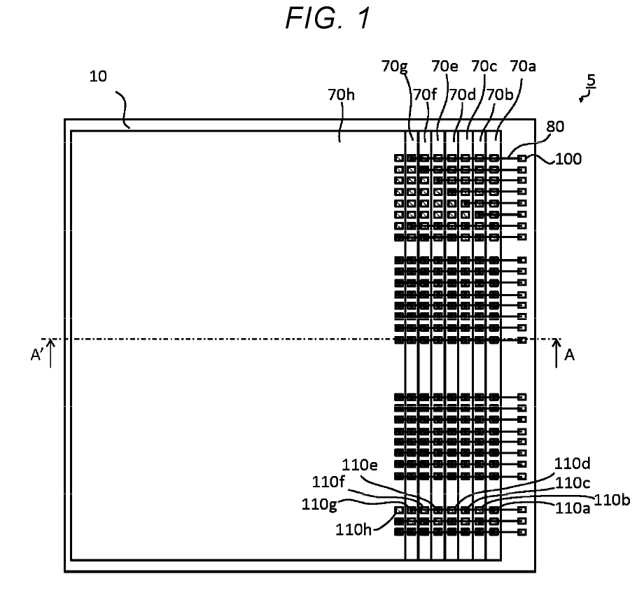

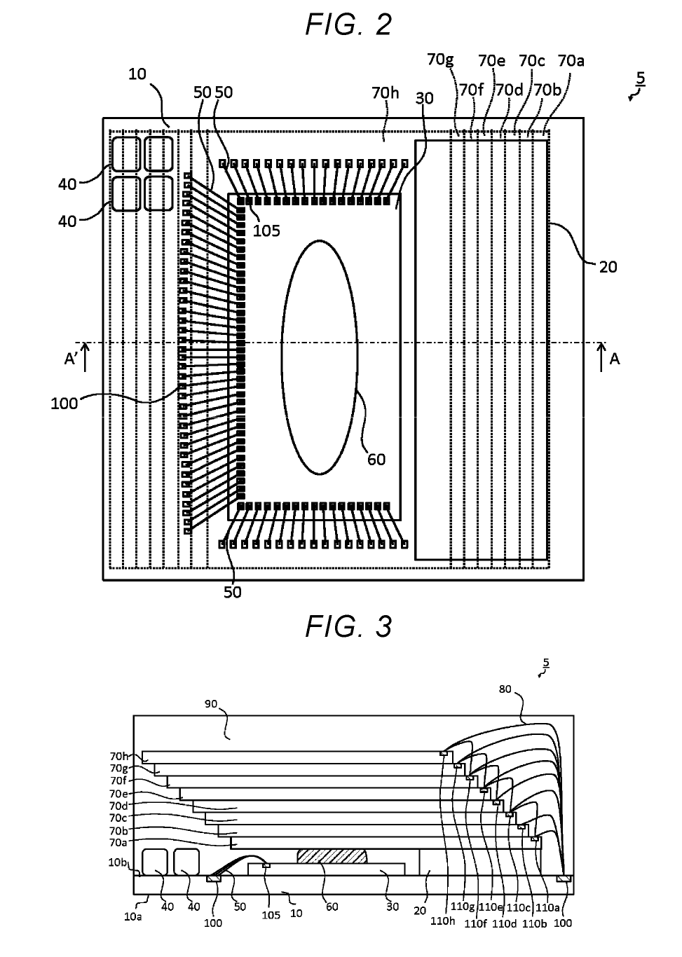

A semiconductor device according to the first embodiment will be described with reference to FIGS. 1 to 3. In FIGS. 1 and 2, a sealing resin layer 90 is not shown for the sake of convenience. In FIG. 3, the sealing resin layer 90 is shown as a transparent layer for the sake of convenience.

First, a cross section of a semiconductor device 5 will be described with reference to FIG. 3.

The semiconductor device 5 depicted in FIG. 3 includes the wiring substrate 10. The wiring substrate 10 is, for example, an insulating resin wiring substrate or a ceramic wiring substrate on or in which a wiring layer (not depicted in the drawing) is provided. Specifically, for example, a printed wiring board or the like using a glass-epoxy resin is used. Alternatively, a silicon interposer, a lead frame, or the like may be used.

The wiring substrate 10 has a first surface 10a and a second surface 10b. On the first surface 10a, an external terminal (a protrusion terminal formed by using a solder ball or the like) for a BGA package and an external terminal (a metal land formed by metal plating or the like, which is not depicted in the drawing) for an LGA package are formed.

On the second surface 10b of the wiring substrate 10, a spacer (a supporting member) 20, a first semiconductor chip 30, and circuit elements 40 are arranged.

The spacer 20 supports second semiconductor chips 70a to 70h. The second semiconductor chips 70a to 70h are supported by the spacer 20 in positions spaced from the wiring substrate 10. As the spacer 20, for example, a rigid member in a solid state, such as silicon, is used.

The first semiconductor chip 30 is, for example, a memory controller chip that communicates a signal with an external device. In addition to the memory controller chip, for example, system LSI ships such as an interface chip, a logic chip, and an RF chip may be used. Moreover, a plurality of first semiconductor chips 30 may be used.

In the first semiconductor chip 30, first electrode pads 105 for connecting the first semiconductor chip 30 with the outside are provided. To each first electrode pad 105, one end of a corresponding first bonding wire 50 is connected. The other end of the first bonding wire 50 is connected to a corresponding electrode 100 of the wiring substrate 10. That is, the first semiconductor chip 30 is electrically connected to the wiring substrate 10 via the first bonding wires 50. As the first bonding wires 50, for example, metal wires such as an Au wire and a Cu wire are used.

The first semiconductor chip 30 may be electrically connected to the wiring substrate 10 via a through electrode provided in the first semiconductor chip 30 and a bump electrode provided on the surface thereof in place of the first bonding wires 50.

The circuit elements 40 are, for example, a resistor, a coil, a capacitor, and the like. For example, the capacitor used as the circuit element 40 stabilizes a power-supply voltage of the semiconductor device 5, the first semiconductor chip 30, the second semiconductor chips 70a to 70h which will be described later, and the like. Alternatively, the capacitor allows the semiconductor device 5 and the like to temporarily operate in case of a power failure, using the electrical charge stored in the capacitor. Alternatively, the capacitor performs timing adjustment between the second semiconductor chips 70a to 70h. As a result of solder or a conductive adhesive material being provided at connecting terminals (not depicted in the drawing) of the circuit elements 40, the circuit elements 40 are fixed to the wiring substrate 10 and are electrically connected thereto.

In a part of a region on the first semiconductor chip 30, a resin member 60 is provided. As the resin member 60, for example, a thermoset resin is used. More specifically, a silicone resin, an acrylic resin, or an epoxy resin is used.

On the spacer 20 and the resin member 60, the second semiconductor chips 70a to 70h are provided. Hereinafter, when there is no need to distinguish the second semiconductor chips 70a to 70h from one another, each of the second semiconductor chips 70a to 70h will be referred to simply as the second semiconductor chip 70. Of the second semiconductor chips 70a to 70h, the lowermost second semiconductor chip is the second semiconductor chip 70a. On the second semiconductor chip 70a, the second semiconductor chips 70b, 70c, 70d, 70e, 70f, 70g, and 70h are arranged in this order in a stepwise shape. In other words, a part of the upper surface of each second semiconductor chip 70 is not covered with another second semiconductor chip 70. Furthermore, in other words, a part of the upper surface of each second semiconductor chip 70 is arranged so as to be in contact with the sealing resin layer 90. Examples of the second semiconductor chip 70 include a semiconductor memory chip such as a NAND flash memory, but the examples are not limited thereto, and any semiconductor chip may be used. Moreover, a structure formed by stacking eight second semiconductor chips 70 is depicted as an example, but any number of second semiconductor chips 70 may be used as long as one or more second semiconductor chips 70 are used.

The second semiconductor chips 70a to 70h include second electrode pads 110a to 110h, respectively. Hereinafter, when there is no need to distinguish the second electrode pads 110a to 110h from one another, the second electrode pads 110a to 110h will be referred to simply as the second electrode pads 110. The second electrode pads 110 are arranged in a part of the upper surface of the second semiconductor chip 70.

Incidentally, at least a part of a region in which the second electrode pads 110 are provided is provided in a region which overlaps with the spacer 20. In other words, the spacer 20 and the second electrode pads 110 are provided so that the spacer 20 and the second electrode pads 110 overlap one another when the spacer 20 and the second electrode pads 110 are projected in the first direction onto a plane orthogonal to the first direction.

To the second electrode pads 110, second bonding wires 80 are connected. Moreover, the second bonding wires 80 connect to the electrodes 100 provided on the wiring substrate 10. That is, the second semiconductor chips 70 electrically connect to the wiring substrate 10 via the second bonding wires 80. As the second bonding wires 80, metal wires such as Au wires and Cu wires are used.

The sealing resin layer 90 is provided so as to seal the first semiconductor chip 30, the second semiconductor chips 70, the circuit elements 40, the resin member 60, the first bonding wires 50, the second bonding wires 80, and the like integrally.

With reference to FIGS. 1 and 2, a plan view will be described. In FIG. 2, in order to explain a structure of a portion under the second semiconductor chips 70, the second semiconductor chips 70 are not depicted, and, for the sake of explanation, the outlines thereof are indicated by dotted lines.

As depicted in FIG. 1, the second semiconductor chips 70 are arranged by being stacked in a stepwise shape, i.e., each of the second semiconductor chips 70 is laterally offset from the second semiconductor chip 70 therebelow. In each second semiconductor chip 70, the second electrode pads 110 are provided. As mentioned above, the second bonding wires 80 electrically connect to the second electrode pads 110 and the electrodes 100. The second bonding wires 80 and the second electrode pads 110 are connected by ball bonding, for example. Moreover, the second bonding wires 80 and the electrodes 100 may be connected by stitch bonding, for example.

Incidentally, in FIG. 1, the second semiconductor chips 70 have substantially the same size, but the example is not limited thereto. For example, by making the second semiconductor chip 70h smaller than the second semiconductor chips 70a to 70g located under the second semiconductor chip 70h, the physical stability obtained when the second semiconductor chips 70 are stacked in a stepwise shape may be improved. On the other hand, by making the lowermost second semiconductor chip 70a smaller than the second semiconductor chips 70b to 70h located above the second semiconductor chip 70a, the other parts such as the circuit elements 40 may be easily mounted on the wiring substrate 10.

Next, the structure of a portion under the second semiconductor chips 70 will be described with reference to FIG. 2.

On the wiring substrate 10, the spacer 20, the first semiconductor chip 30, and the circuit elements 40 are arranged. The spacer 20, the first semiconductor chip 30, and the circuit elements 40 are arranged so that the spacer 20, the first semiconductor chip 30, and the circuit elements 40 do not overlap one another in a plan view when viewed from above. In other words, the spacer 20, the first semiconductor chip 30, and the circuit elements 40 are arranged so that the spacer 20, the first semiconductor chip 30, and the circuit elements 40 do not overlap one another when the spacer 20, the first semiconductor chip 30, and the circuit elements 40 are projected in the first direction onto a plane orthogonal to the first direction. In other words, when the spacer 20, the first semiconductor chip 30, and the circuit elements 40 are projected onto the wiring substrate 10 in the first direction, the spacer 20 is projected onto a first region, the first semiconductor chip 30 is projected onto a second region, and the circuit elements 40 are projected onto a third region. Here, the first region, the second region, the third region are different from each other.

In apart of a region directly on the first semiconductor chip 30, the resin member 60 is arranged so as to be substantially elliptical in shape. Moreover, the resin member 60 is formed in a part of a region immediately below the second semiconductor chip 70a. In other words, when the first semiconductor chip 30, the second semiconductor chip 70a, and the resin member 60 are projected in the first direction onto a plane orthogonal to the first direction, the resin member 60 overlaps with a part of the first semiconductor chip 30 and the resin member 60 overlaps with a part of the second semiconductor chip 70a.

Furthermore, the second semiconductor chips 70 are provided above the spacer 20, the first semiconductor chip 30, the circuit elements 40, and the resin member 60. In other words, the stack of second semiconductor chips 70 are arranged in locations which overlap with the spacer 20, the first semiconductor chip 30, the circuit elements 40, and the resin member 60 in a plan view when viewed from above. In addition, each second semiconductor chip 70 has an area larger than the area of the spacer 20, the area of the first semiconductor chip 30, and the area of the circuit element 40.

To each first electrode pad 105 of the first semiconductor chip 30, one end of a corresponding first bonding wire 50 is connected by ball bonding, for example, as mentioned above. The other end of the first bonding wire 50 is connected to a corresponding electrode 100 provided in the wiring substrate 10 by the stitch bonding, for example.

### A Manufacturing Method According to the First Embodiment

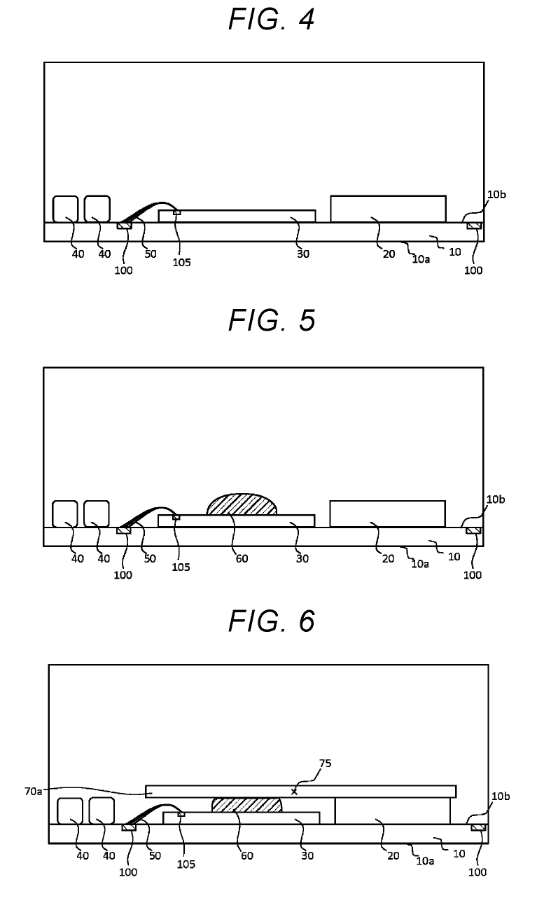

A manufacturing method according to the first embodiment will be described with reference to FIGS. 4 to 6. First, as depicted in FIG. 4, a process by which various members are bonded to the wiring substrate 10 will be described.

First, the circuit elements 40 are bonded to the wiring substrate 10. Specifically, solder or a conductive adhesive is applied to the wiring substrate 10. After electrode portions of the circuit elements 40 are arranged on the adhesive material, the circuit elements 40 are bonded to the wiring substrate 10 by the application of heat.

Next, the spacer 20 is bonded to the wiring substrate 10 by the following method, for example. A die attach film (DAF) is bonded to one surface of the spacer 20. The spacer 20 is arranged on the wiring substrate 10 with the surface to which the DAF is bonded with facing downward. Then, the DAF is cured by heating and the spacer 20 is bonded to the wiring substrate 10.

Incidentally, this curing by heating may be performed so as to obtain a partially cured state, not a completely cured state. In this case, curing simply has to be performed by heating again after bonding of the first semiconductor chip 30, the second semiconductor chips 70, and the like performed by a DAF in the partially cured state.

The first semiconductor chip 30 is bonded to the wiring substrate 10 in the same manner as the spacer 20. That is, a DAF is bonded to the first semiconductor chip 30, the first semiconductor chip 30 is arranged on the wiring substrate 10, and the first semiconductor chip 30 is bonded to the wiring substrate 10 by heating.

After the first semiconductor chip 30 is arranged on the wiring substrate 10, the first bonding wires 50 are connected to the first semiconductor chip 30 and the wiring substrate 10. The order of bonding may be normal bonding, reverse bonding, or the like, and each bonding may be performed by using various methods such as stitch bonding or ball bonding.

As a result of the above process, the state depicted in FIG. 4 is obtained.

As depicted in FIG. 5, the resin member 60 is applied to a part of a region on the first semiconductor chip 30. Preferably, the highest portion of the resin member 60 is higher than the top of the spacer 20. Here, the resin member 60 is a liquid resin and, for example, a thermoset resin such as a silicone resin, an acrylic resin, or an epoxy resin is used. Preferably, the resin member 60 has a viscosity that does not allow the resin member 60 to spread and entirely flow to the side surfaces of the first semiconductor chip 30 and the wiring substrate 10 after the application of the resin member 60. However, preferably, the resin member 60 is not completely cured until at least the second semiconductor chip 70a is bonded thereto.

As depicted in FIG. 6, the second semiconductor chip 70a is bonded to the spacer 20 and the resin member 60. After a DAF is bonded to a surface of the second semiconductor chip 70a, the surface arranged as the underside of the second semiconductor chip 70a, the second semiconductor chip 70a is arranged on the resin member 60 and the spacer 20. Then, the second semiconductor chip 70a is bonded to the spacer 20 and the resin member 60 by heating.

The spacer 20 is solid rigid matter such as silicon. Therefore, when the second semiconductor chip 70a is bonded to the spacer 20, the spacer 20 supports the second semiconductor chip 70a with little change in the height thereof. The upper surface of the spacer 20 and the lower surface of the second semiconductor chip 70a are brought into intimate contact with each other. Thus, the height of the lower surface of the second semiconductor chip 70a is substantially the same as the height of the upper surface of the spacer 20.

On the other hand, since the resin member 60 has viscosity, the resin member 60 is deformed by being pressed by the second semiconductor chip 70a. In addition, since the height of the lower surface of the second semiconductor chip 70a becomes substantially the same as the height of the upper surface of the spacer 20, the height of the upper surface of the resin member 60 is adjusted so as to become substantially the same as the height of the upper surface of the spacer 20 in a self-aligned manner. Therefore, the height of the resin member 60 becomes substantially the same as the height of the lower surface of the second semiconductor chip 70a.

As depicted in FIG. 6, the center of mass 75 of the second semiconductor chip 70a is not in a region immediately above the spacer 20. That is, the second semiconductor chip 70a cannot be supported only by the spacer 20. Therefore, preferably, the resin member 60 has an adequate viscosity that allows the resin member 60 to support the second semiconductor chip 70a in an at least partially cured state. Specifically, preferably, the resin member 60 has a viscosity of at least 50 to 1,000 Pa·s in a partially cured state.

Incidentally, the resin member 60 does not necessarily have to be capable of supporting the second semiconductor chip 70a in an uncured state. For example, the semiconductor device 5 simply has to be heated with the second semiconductor chip 70a being held on the spacer 20 and the resin member 60 with an armor the like of an apparatus. Moreover, when the center of mass 75 is in a region immediately above the spacer 20, since the second semiconductor chip 70a is supported by the spacer 20, high viscosity of the resin member 60 is not necessarily required.

As depicted in FIG. 3, the second semiconductor chip 70b is arranged on the second semiconductor chip 70a. For example, a DAF is bonded to the lower surface of the second semiconductor chip 70b in advance, and the second semiconductor chip 70b is arranged on the second semiconductor chip 70a and is then heated, whereby the second semiconductor chip 70b is bonded to the second semiconductor chip 70a.

Bonding of the second semiconductor chips 70c to 70h is also performed in the same manner as bonding of the second semiconductor chip 70b. After bonding of the second semiconductor chip 70h is completed, heat is applied. As a result of the heating, the DAF and the resin member 60 are completely cured.

After the second semiconductor chips 70 are arranged, the second bonding wires 80 are formed by being connected to the second semiconductor chips 70 and the electrodes 100. The order of bonding may be normal bonding, reverse bonding, or the like, and each bonding may be performed by using various methods such as stitch bonding or ball bonding.

Then, the sealing resin layer 90 is formed. The sealing resin layer 90 is formed by, for example, putting the semiconductor device 5 into a mold, pouring a resin into the mold, and then curing the resin. Incidentally, the sealing resin layer 90 may be formed by putting the semiconductor device 5 into a mold containing a resin and then curing the resin. That is, the sealing resin layer 90 may be formed by so-called compression molding. Since compression molding does not allow the resin to flow, the deformation of the first bonding wires 50 and the second bonding wires 80 may be prevented more effectively.

### Effects of the First Embodiment

According to this embodiment, the second semiconductor chip 70a is arranged on the spacer 20 and the resin member 60. Since the spacer 20 is solid rigid matter, the lower surface of the second semiconductor chip 70a is supported by the upper surface of the spacer 20. On the other hand, since the resin member 60 is in an uncured state when the second semiconductor chip 70a is arranged, the resin member 60 changes the shape thereof in accordance with the lower surface of the second semiconductor chip 70a. The resin member 60 may support the second semiconductor chip 70a by making the height thereof equal to the height of the spacer 20 by being deformed.

That is, since the resin member 60 is deformed, the second semiconductor chip 70a may be supported via the resin member 60 provided on the first semiconductor chip 30 without a member having a height corresponding to a difference between the height of the spacer 20 and the height of the first semiconductor chip 30 being prepared on the first semiconductor chip 30. In particular, the height of the first semiconductor chip 30 varies due to variations in manufacturing. The semiconductor device 5 according to this embodiment may be manufactured without being affected by the variations in the height of the first semiconductor chip 30.

According to this embodiment, the second semiconductor chips 70 may be supported by the spacer 20 and the resin member 60 arranged on the first semiconductor chip 30. That is, there is no need to dispose another spacer on the wiring substrate 10 in addition to the spacer 20. Since there is no need to dispose an extraneous spacer, the semiconductor device 5 may be miniaturized. Moreover, the absence of an extraneous spacer reduces the possibility of the flow of the resin being interfered with during forming the sealing resin layer 90 and allows the resin to be easily poured into a mold. Furthermore, the area of the first semiconductor chip 30 may be made larger, whereby higher performance may be achieved.

Moreover, according to this embodiment, each second semiconductor chip 70 has an area larger than the area of the spacer 20, the area of the first semiconductor chip 30, and the area of the circuit element 40. Thus, by disposing the spacer 20, the first semiconductor chip 30, the circuit elements 40, and the first bonding wires 50 in regions which overlap with the second semiconductor chips 70 when the spacer 20, the first semiconductor chip 30, the circuit elements 40, and the first bonding wires 50 are projected in the first direction, the semiconductor device 5 may be miniaturized.

Furthermore, as a result of the circuit elements 40 being encapsulated in regions which overlap with the second semiconductor chips 70, as compared with a case in which a circuit element is separately provided outside the semiconductor device 5, the total area of the circuit element and the semiconductor device 5 may be reduced.

In addition, according to this embodiment, the second electrode pads 110 and the spacer 20 are arranged in regions which overlap one another when the second electrode pads 110 and the spacer 20 are projected onto a plane orthogonal to the first direction. As a result of the second electrode pads 110 and the spacer 20 being arranged in this manner, the pressure which is applied during bonding the second bonding wires 80 may be supported directly by the spacer 20, whereby bonding of the second bonding wires 80 may be performed with stability.

Furthermore, according to this embodiment, the first semiconductor chip 30 is formed in a region closer to the wiring substrate 10 than the second semiconductor chips 70. When the first semiconductor chip 30 is, for example, a memory controller and the second semiconductor chips 70 are semiconductor memory chips, the first semiconductor chip 30 has to exchange more data and commands, as compared with the second semiconductor chips 70. By forming the first semiconductor chip 30 near the wiring substrate 10, the first bonding wires 50 may be easily formed so as to have a uniform length and signal delays between the first bonding wires 50 may be reduced. This is very important in achieving high-speed operation.

Moreover, when the first semiconductor chip 30 is, for example, a memory controller and the second semiconductor chips 70 are semiconductor memory chips, the number of first bonding wires 50 may be greater than the number of second bonding wires 80. Thus, when the first bonding wires 50 are great in number, by disposing the first semiconductor chip 30 in a region near the wiring substrate 10, bonding to the first semiconductor chip 30 may be easily performed with greater flexibility. For example, as depicted in FIG. 1, the second bonding wires 80 have to be connected to one side of each of the second semiconductor chips 70a to 70g, the side exposed from the upper side. On the other hand, as depicted in FIG. 2, the first bonding wires 50 may be connected to three sides of the first semiconductor chip 30.

### Second Embodiment

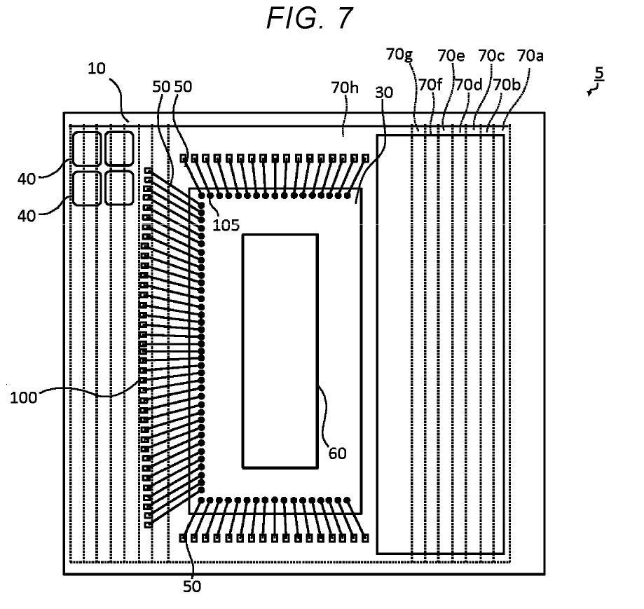

A second embodiment will be described with reference to FIG. 7. FIG. 7 is a plan view corresponding to FIG. 2.

In this embodiment, in place of the liquid resin member 60, a sheet-like resin member 60 is used. By using the sheet-like resin member 60, the resin member 60 may be arranged on the first semiconductor chip 30 more easily.

Moreover, the effects described in the first embodiment may be obtained also in this embodiment.

### Third Embodiment

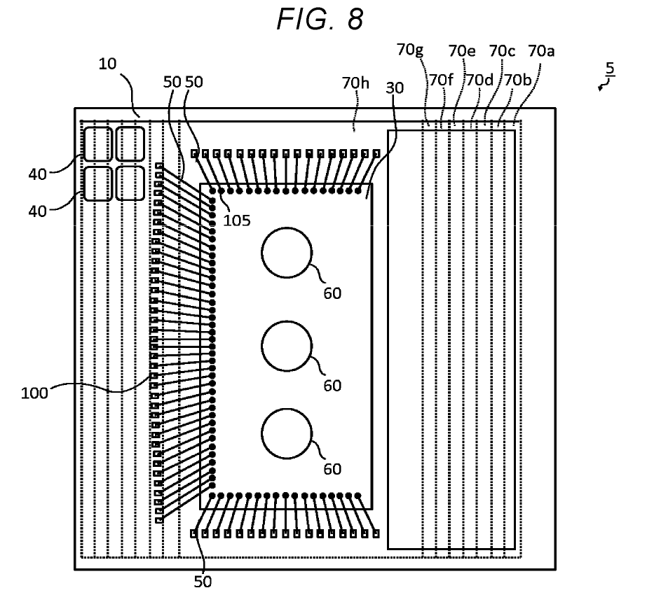

A third embodiment will be described with reference to FIG. 8. FIG. 8 is a plan view corresponding to FIG. 2.

In this embodiment, the liquid resin member 60 is applied to the first semiconductor chip 30 in three places, not in one place.

By disposing the resin member 60 in multiple places in this manner, the second semiconductor chips 70 are uniformly supported by the resin members 60 in the multiple places, whereby higher reliability may be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a wiring substrate;
a first semiconductor chip provided on the wiring substrate;
a supporting member provided on the wiring substrate in a region which does not overlap with the first semiconductor chip in a plan view when viewed from a direction perpendicular to the wiring substrate;
a resin member provided on the first semiconductor chip; and
a second semiconductor chip provided on the supporting member and the resin member.

2. The device according to claim 1, further comprising:
a circuit element provided on the wiring substrate.

3. The device according to claim 2, wherein
the first semiconductor chip and the circuit element are provided in regions, at least a part of which overlaps with the second semiconductor chip when the first semiconductor chip and the circuit element are projected onto a plane perpendicular to the wiring substrate.

4. The device according to claim 1, wherein
an area of the second semiconductor chip, when viewed from the first direction, is larger than an area of the first semiconductor chip, an area of the supporting member, and an area of the resin member.

5. The device according to claim 1, wherein
the resin member is provided in a region which overlaps with the first semiconductor chip when the resin member is projected onto a plane perpendicular to the wiring substrate.

6. The device according to claim 5, wherein
the resin member is substantially elliptic in shape.

7. The device according to claim 6, wherein
the resin member includes a plurality of resin members, each substantially elliptical in shape.

8. The device according to claim 1, wherein
the resin member comprises a thermoset resin having a viscosity of 50 to 1,000 Pa·s in an uncured state.

9. The device according to claim 1, wherein
the second semiconductor chip electrically connects to a metal wire via an electrode pad, and
the electrode pad is provided in a region which overlaps with the supporting member in a plan view when viewed from the direction perpendicular to the wiring substrate.

10. The device according to claim 1, wherein
the first semiconductor chip electrically connects to the wiring substrate by first metal wires,
the second semiconductor chip electrically connects to the wiring substrate by second metal wires, and
the number of the second metal wires is greater than the number of the first metal wires.

11. The device according to claim 10, wherein
the second semiconductor chip comprises a plurality of semiconductor chips including a memory element, and
the first semiconductor chip is a semiconductor chip including a controller of the memory element.

12. A method for manufacturing a semiconductor device, comprising:
providing a first semiconductor chip in a first region on a wiring substrate;
providing a supporting member in a second region on the wiring substrate;
providing a resin member in at least a portion on the first semiconductor chip; and
providing a second semiconductor chip on the supporting member and the resin member.

13. The method according to claim 12, wherein
a circuit element is provided on the wiring substrate before the second semiconductor chip is provided on the wiring substrate.

14. The method according to claim 13, wherein
the circuit element is provided below the second semiconductor chip.

15. The method according to claim 12, wherein
the resin member is cured by heating after the second semiconductor chip is provided on the supporting member and the resin member.

16. The method according to claim 12, wherein
after the first semiconductor chip is provided in a first region on a wiring substrate, first metal wires electrically connecting the wiring substrate and the first semiconductor chip are formed,
after the second semiconductor chip is provided on the supporting member and the resin member, second metal wires electrically connecting the wiring substrate and the second semiconductor chip are formed, and
the number of the second metal wires is greater than the number of the first metal wires.

17. A semiconductor device, comprising:
a wiring substrate having separate non-overlapping first, second and third regions;
a solid support member disposed on the wiring substrate in the first region;
a semiconductor chip of a first type mounted to the wiring substrate in the second region;
at least one circuit element mounted to the wiring substrate in the third region; and
a semiconductor chip of a second type mounted on the solid support member and extending over the semiconductor chip of the first type, wherein the semiconductor chip of the second type, when mounted on the solid support member, has a center of mass which is not located in the first region.

18. The semiconductor device of claim 17; wherein a resin extends between the semiconductor chip of the first type and the semiconductor chip of the second type.

19. The semiconductor device of claim 17, further including a plurality of semiconductor chips of the second type connected together in stair-step relationship to one another, and wherein at least one of the semiconductor chips of the second type extends over the third region.

20. The semiconductor device of claim 17, wherein the semiconductor chip of the first type is a non-memory chip, and the semiconductor chip of the second type is a memory chip.
